(19) United States
(12) Patent Application Publication
(10) Pub. No.: US 2005/0233567 A1
(43) Pub. Date: Oct. 20, 2005

(54) Method of manufacturing multi-stack package

(76) Inventors: Se-Nyun Kim, Chungcheongnam-do (KR); Heung-Kyu Kwon, Gyeonggi-do (KR); Ki-Myung Yoon, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/053,599

(22) Filed: Feb. 7, 2005

(30) Foreign Application Priority Data
Feb. 6, 2004 (KR) 2004-8062

(51) Int. Cl. H01L 21/44

(52) U.S. Cl. 438/612

(57) ABSTRACT

A method of manufacturing a multi-stack package that ensures easy application of a solder paste or a flux. The method includes forming a first package comprising a first substrate on which bumps are arranged and a second package comprising a second substrate on which electrode pads corresponding to the bumps are arranged, applying a solder paste on the bumps of the first package, and electrically connecting the bumps of the first package and the electrode pads of the second package.

This application claims priority from Korean Patent Application No. 10-2004-0008062 filed on Feb. 6, 2004, the disclosure of which is incorporated herein in its entirety by reference.

### BACKGROUND OF THE INVENTION

1. Field of the Invention

The present invention relates to a method of manufacturing a multi-stack package, and more particularly to a method of manufacturing a multi-stack package which ensures easy application of a solder paste or a flux to interconnect between bumps of a first package and corresponding electrode pads of a second package without being restricted by the structural shape of the second package.

2. Description of the Related Art

A close proximity interconnection of arrays of semiconductor devices broadens their application range. In this regard, various array structures of two or more semiconductor chips which are in close proximity with space-saving effects have been suggested. Multi-chip module (MCM) technology has been developed in which multiple semiconductor chips are mounted on a package. Also developed is multi-stack package technology in which two or more packages are stacked.

A general multi-stack semiconductor package will now be described. Generally, a manufacturing method for semiconductor packages, for example, ball grid array (BGA) semiconductor packages, includes: cutting a wafer having multiple semiconductor chips thereon into individual chips (cutting process), bonding these semiconductor chips to predetermined areas of a previously prepared printed circuit board (PCB) (semiconductor chip bonding process), interconnecting the semiconductor chips and the predetermined areas of the PCB using conductive wires (wire bonding process), encapsulating the semiconductor chips with encapsulation means to protect the semiconductor chips from an outer environment (molding process), attaching solder balls used as input/output terminals of the PCB to a surface of the PCB (solder ball attaching process), and dicing the PCB into predetermined semiconductor package units (singulation process). An assembly of two or more semiconductor packages thus manufactured is called as multi-stack package.

A surface mount technology (SMT), in which semiconductor packages are mounted on a surface of a system board, is disclosed in Korean Patent No. 0398716. According to the disclosed method, a package having solder bumps on a chip electrode is bonded to a circuit board or an intermediate substrate on which a solder paste is printed. According to the disclosed patent, however, only materials of the solder bumps and the solder paste are described but there is no description about a method of applying the solder paste onto the circuit board or the solder bumps of the package.

Conventionally, a first package with solder bumps is mounted on a semiconductor substrate or a second package by stencil printing a flux or a solder paste onto electrode pads formed on the semiconductor substrate or the second package, and electrically connecting the solder bumps and the electrode pads. However, such a stencil printing has a problem in a package-to-package mounting, unlike in a package-to-semiconductor substrate mounting.

That is, in the case of forming a multi-stack package in which multiple packages are stacked via bumps, the presence of separate structures on semiconductor substrates of packages having electrode pads corresponding to the bumps thereon makes it difficult to apply a flux or a solder paste on a package by stencil printing.

Hereinafter, a conventional method for manufacturing a multi-stack package will be described with reference to FIG. 1.

FIG. 1 is a sectional view that illustrates a conventional method of manufacturing a multi-stack package in which two packages are stacked. Referring to FIG. 1, a conventional multi-stack package includes an upper package 160 and a lower package 165. As described above, the upper package 160 is formed by performing a wafer cutting process, a semiconductor chip bonding process, a wire bonding process, a molding process, a solder ball attaching process, and a singulation process. The lower package 165 is formed in the same manner as in the formation of the upper package 160 except that a second microelectronic semiconductor chip 125 is mounted on a second substrate 115 via a flip chip 135 instead of a bonding wire 130.

First bumps 150 of the upper package 160 are electrically connected to corresponding electrode pads 157 of the lower package 165. Here, a flux 175 is previously applied onto the electrode pads 157 of the lower package 165 to which the first bumps 150 are connected. The application of the flux 175 is generally performed by stencil printing. However, in a case where the lower package 165 has the second microelectronic semiconductor chip 125 thereon, as shown in FIG. 1, the stencil printing of the flux 175 on the electrode pads 157 may be difficult.

In FIG. 1, reference numeral 110 indicates a first substrate, reference numeral 120 indicates a first microelectronic chip, reference numerals 140 and 145 each indicate encapsulation means, and reference numeral 155 indicates second bumps.

### SUMMARY OF THE INVENTION

The present invention provides a method of manufacturing a multi-stack package which ensures easy application of a solder paste to interconnect between bumps of a first package and corresponding electrode pads of a second package without being restricted by the structural shape of the second package.

The present invention also provides a method of manufacturing a multi-stack package which ensures easy application of a flux for interconnection between bumps of a first package and corresponding electrode pads of a second package without being restricted by the structural shape of the second package.

According to an aspect of the present invention, a method of manufacturing a multi-stack package comprises: forming a first package comprising a first substrate on which bumps are arranged and a second package comprising a second substrate on which electrode pads corresponding to the bumps are arranged, applying a solder paste on the bumps of the first package, and electrically connecting the bumps of the first package and the electrode pads of the second package.

According to another aspect of the present invention, a method of manufacturing a multi-stack package includes forming a first package that comprises a first substrate on which bumps are arranged and a second package that comprises a second substrate on which electrode pads corresponding to the bumps are arranged, applying a flux on the bumps of the first package, and electrically connecting the bumps of the first package and the electrode pads of the second package.

According to still another aspect of the present invention, a method of manufacturing a multi-stack package includes forming a first package that comprises a first substrate on which bumps are arranged and a second package that comprises a second substrate on which electrode pads corresponding to the bumps are arranged, applying a solder paste on the electrode pads of the second package using a dotting tool, and electrically connecting the bumps of the first package and the electrode pads of the second package.

According to yet another aspect of the present invention, a method of manufacturing a multi-stack package includes forming a first package that comprises a first substrate on which bumps are arranged and a second package that comprises a second substrate on which electrode pads corresponding to the bumps are arranged, applying a flux on the electrode pads of the second package using a dotting tool, and electrically connecting the bumps of the first package and the electrode pads of the second package.

### BRIEF DESCRIPTION OF THE DRAWINGS

The above and other features and advantages of the present invention will become more apparent by describing in detail exemplary embodiments thereof with reference to the attached drawings.

FIG. 1 is a sectional view that illustrates a conventional method of manufacturing a multi-stack package in which two packages are stacked.

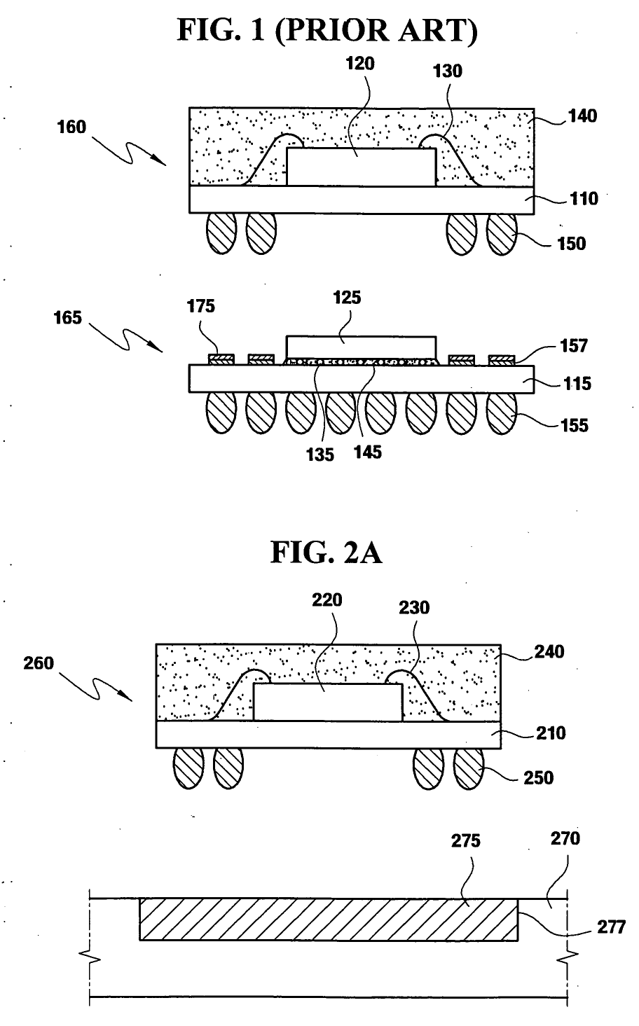

FIGS. 2A through 2D are cross-sectional views illustrating sequential manufacturing processes for a multi-stack package according to an embodiment of the present invention;

FIG. 3 is a cross-sectional view illustrating a method of manufacturing a multi-stack package according to another embodiment of the present invention; and

FIGS. 4A and 4B are enlarged cross-sectional views of part A of FIG. 3.

### DETAILED DESCRIPTION OF THE PREFERRED EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

The following embodiments of the present invention constitute high-frequency microprocessors, application specific integrated circuit (ASIC) products, or high-speed memory devices such as dynamic random access memories (DRAMs) and static random access memories (SRAMs). Most of these devices have multi-pin input/output terminals. For a multi-pin structure, most of the packages constituting these devices may be formed of plastic or ceramic pin grid array (PGA) packages, land grid array (LGA) packages, ball grid array (BGA) packages, quad flat packages or lead frame packages.

A substrate that can be used herein may be a printed circuit board (PCB), a ceramic substrate, a metal substrate, or a silicon substrate, which can be used in packages such as PGA packages, LGA packages, BGA packages, quad flat packages, and lead frame packages.

Generally, packages can be classified into resin-sealed packages, tape carrier packages (TCPs), glass-sealed packages, and metal-sealed packages according to a sealant used. Packages can also be classified into an insertion technology type and a surface mount technology (SMT) type according to a mount technology. Dual in-line packages (DIPs) and PGA packages are representatives of the insertion technology type packages. Quad flat packages (QFPs), plastic leaded chip carrier (PLCC) packages, ceramic leaded chip carrier (CLCC) packages, and BGA packages are representatives of the SMT type packages.

It is common for one microelectronic chip to be contained in a single package. However, two or more chips may be contained in a single package. The latter case is called a multi chip package (MCP) or a multi chip module (MCM). A structure obtained by stacking two or more packages is called as a multi-stack package. These packages with multiple chips have a cost-saving effect and excellent performance. They have increased memory capacity and fast processing speed, and thus they are ideal packages for memory modules, core logic chipsets, microprocessors, and micro-controller systems which require excellent electrical performance, high board density, and high surface mount yield. Therefore, the packages with multiple chips are mainly used in laptop computers, portable computers, sub-notebooks, telecom, wireless equipment, and PC cards.

Microelectronic chips to be mounted in packages can be selected from many semiconductor devices. Preferred examples of microelectronic chips as used herein include logic and analog devices, application specific products (ASPs), and wireless products. In such exemplary applications, each chip in a set of chips can be easily used. A precise design and a developing time are required for a single chip to realize the performance of a chip stack. Furthermore, there arise problems such as a large-scale chip with low early yield and a large-scale package occupying a large space of an expensive substrate. In this regard, the present invention may overcome a space restriction of continuous size-reducing applications such as cellular communication pagers, hard disk drives, laptop computers, and medical equipment.

Examples of microelectronic chips as used herein include highly integrated semiconductor memory chips such as DRAMs, SRAMs, and flash memories, MEMS (Micro Electro Mechanical Systems) chips, optoelectronic chips, and processors such as CPUs and digital signal processors (DSPs). The microelectronic chips may be the same type of electronic chips or different electronic chips for one integral function.

For convenience, embodiments of the present invention will be illustrated in terms of a BGA package and a PCB.

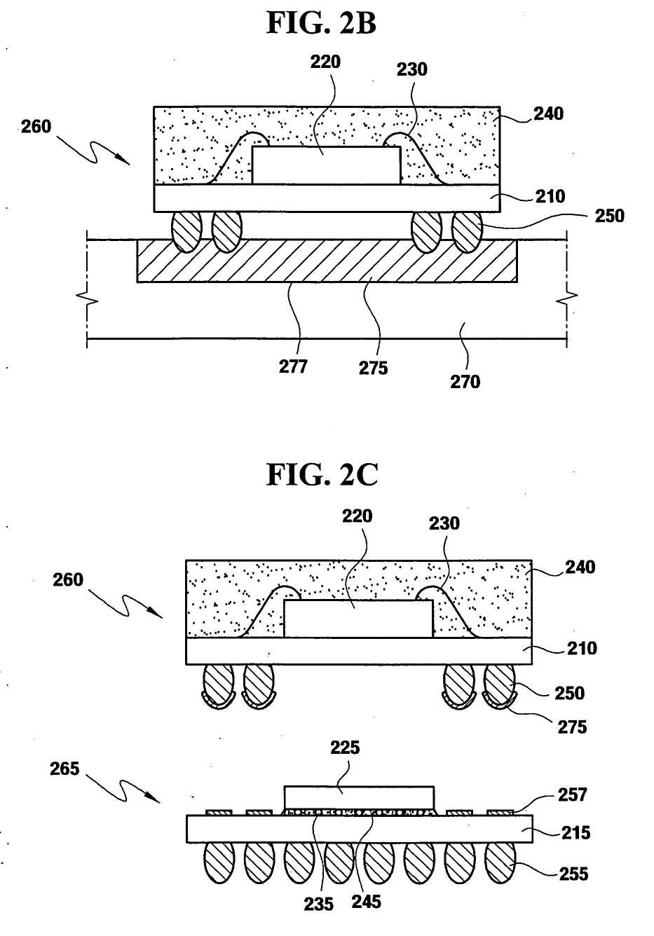

Hereinafter, an embodiment of the present invention will be described with reference to FIGS. 2A through 2D.

Referring to FIG. 2A, a first package 260 is prepared using a general BGA package manufacturing process.

According to the BGA package manufacturing process, a wafer having multiple first microelectronic chips thereon is singulated into individual chips (wafer cutting process). These first microelectronic chips are bonded to predetermined areas of a previously prepared PCB (microelectronic chip bonding process). The microelectronic chips and the predetermined areas of the PCB are interconnected using conductive bond wires (wire bonding process). The microelectronic chips are encapsulated with an encapsulant to protect the microelectronic chips from an external environment (molding process). Bumps used as input/output terminals of the PCB are attached to a surface of the PCB (bump attaching process). And the PCB is diced into predetermined package units (singulation process).

Referring to FIGS. 2A and 2B, the first package 260 in which first bumps 250 are formed on a lower surface of a first substrate 210 are disposed above a reservoir 270 retaining a flux or a solder paste 275 and then the ends of the first bumps 250 of the first package 260 are dipped in the flux or the solder paste 275.

The flux 275 may contain resin as a main component and a trace of a halogen activator such as chlorine, fluorine, and bromine. The flux 275 promotes soldering by removing contaminants or surface oxide films attached to subjects to be soldered, to reduce globulation propensity of a solder on a metal surface so that the solder is well dispersed on the metal surface, and to prevent surface re-oxidation by preventing a soldered subject and a solder surface from being exposed to oxygen.

The solder paste 275 may be a suspension of uniform solder microparticles in a flux medium.

The reservoir 270 retaining the flux or the solder paste 275 is formed with a predetermined depth of a pool 277. The reservoir 270 includes a squeegee (not shown) made of metal or rubber to push the flux or solder paste 275 into the pool 277. Therefore, the flux or solder paste 275 can be filled to a uniform thickness in the reservoir 270.

Referring to FIG. 2C, the first bumps 250 of the first package 260 are disposed above corresponding electrode pads 257 of a second package 265. At this time, the position of the first package 260 may be determined by a recognition mark (not shown) formed on a lower surface of the first bumps 250 or the first substrate 210 of the first package 260. The position of the second package 265 may be determined by a recognition mark (not shown) formed on an upper surface of the electrode pads 257 or a second substrate 215 of the second package 265.

Preferably, the electrode pads 257 of the second package 265 are made of Au/Ni coated Cu or organic surface preservation (OSP) treated Cu. More preferably, the electrode pads 257 covered by a solder are reflowed.

Preferably, the first package 260 and the second package 265 are prepared at the same time. In this embodiment, a second microelectronic chip 225 is mounted on the second substrate 215 using a flip chip 235 instead of using a bonding wire 230 for the first package 260.

Referring to FIG. 2D, when the first package 260 is mounted on the second package 265 so that the first bumps 250 are placed onto the electrode pads 257, the first package 260 and the second package 265 are electrically connected by reflowing.

As described above, according to the illustrative embodiment, even though the second package 265 has the electrode pads 257 and the second microelectronic chip 225 on the same surface, a multi-stack package can be easily embodied regardless of the structural shape of the second package 265.

In addition, since the application and placement of the flux are carried out for each package, unlike a conventional stencil printing method, precise bonding can be accomplished.

Meanwhile, the presence of the second microelectronic chip 225 on the second substrate 215 of the second package 265 often requires a predetermined space between the first package 260 and the second package 265, as shown in FIG. 2D. In this case, when the electrode pads 257 and the first bumps 250 are bonded by the solder paste 275 applied onto the first bumps 250, the space between the first package 260 and the second package 265 can be adjusted as needed.

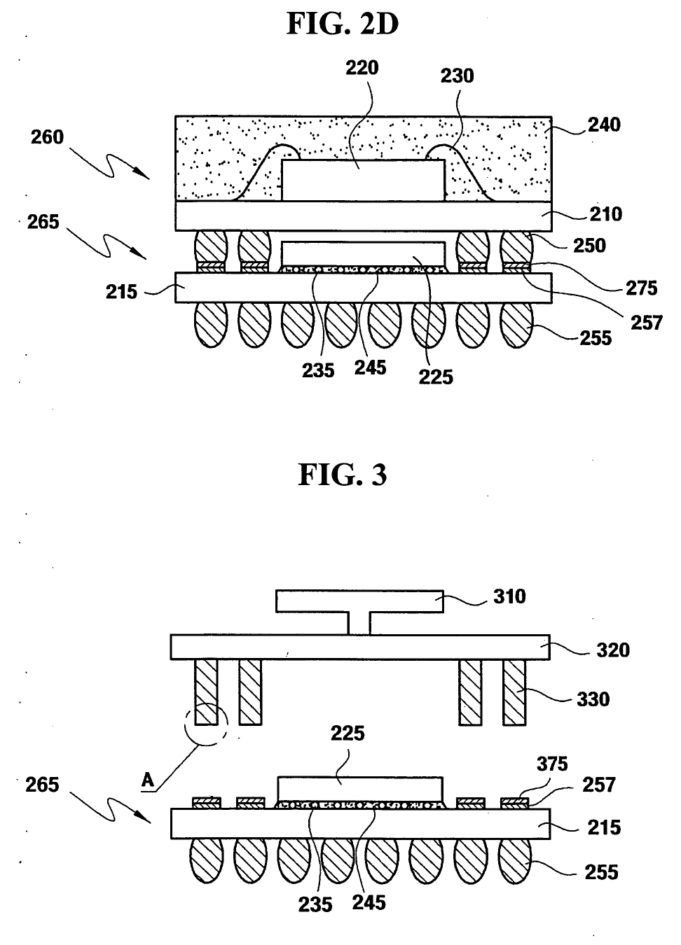

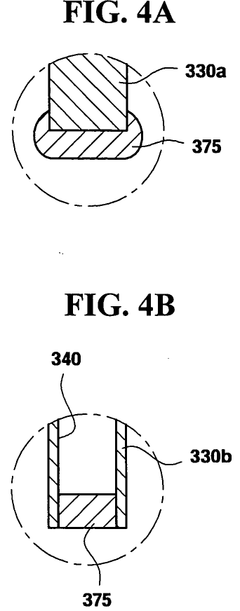

Hereinafter, another embodiment of the present invention will be described with reference to FIGS. 3, 4A, and 4B. FIG. 3 is a sectional view that illustrates a method of manufacturing a multi-stack package according to another embodiment of the present invention. FIGS. 4A and 4B are enlarged cross-sectional views of part A of FIG. 3. For the sake of convenience, the same function elements as those shown in the drawings for the previous embodiment are denoted by the same reference numerals, and an explanation thereof will not be given.

The embodiment as shown in FIG. 3 is different from the previous embodiment only in terms of application of a flux or a solder paste 375.

Referring to FIG. 3, the flux or the solder paste 375 is applied on electrode pads 257 of a second package 265 using a dotting tool 320. The dotting tool 320 is generally provided with multiple needle pins 330 facing the electrode pads 257 so that the flux or the solder paste 375 can be dotted on the electrode pads 257 of a second substrate 215. The dotting tool 320 is electrically connected to a controller 310 so as to be integrally operated. The controller 310 controls the dotting tool 320 so that when ends of the needle pins 330 are dipped in the flux or the solder paste 375 filled in a reservoir (not shown), the dotting tool 320 is transferred to the second substrate 215 and the flux or solder paste 375 of the dotting tool 320 is dotted on the electrode pads 257 of the second substrate 215. The following steps after this step will be of the same as those illustrated in the previous embodiment described above. That is, when the first package 260 is mounted on the second package 265 so that the first bumps 250 are placed onto the electrode pads 257, the first package 260 and the second package 265 are electrically connected by reflowing.

Referring to FIGS. 4A and 4B, the needle pins 330 are divided into rod-type needle pins 330a with a circularly enclosed end and cylinder-type needle pins 330b having a space 340 therein. With respect to the rod-type needle pins 330a, the dipped amount of the flux or the solder paste 375 in the reservoir (not shown) is determined by the diameter of the end of each of the rod-type needle pins 330a. With respect to the cylinder-type needle pins 330b, the dipped amount of the flux or the solder paste 375 in the reservoir (not shown) is determined by the diameter of the space 340 of the end of each of the cylinder-type needle pins 330b.

Application of the flux 375 on the electrode pads 257 using the dotting tool 320 enables easy manufacturing of a multi-stack package regardless of the structural shape of the second package 265. Furthermore, when first bumps 250 are bonded to the electrode pads 257 on which the solder paste 375 is applied by the dotting tool 320, a space between a first package 260 and the second package 265 can be adjusted as needed.

While the invention has been taught with specific reference to these embodiments, someone skilled in the art will recognize that changes can be made in form and detail without departing from the spirit and the scope of the invention. The described embodiments are to be considered in all respects only as illustrative and not restrictive.

As apparent from the above description, a method of manufacturing a multi-stack package according to the present invention ensures easy and precise application of a solder paste or a flux for interconnection between bumps of a first package and corresponding electrode pads of a second package without being restricted by the structural shape of the second package.

Although the invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. A method of manufacturing a multi-stack package, the method comprising:
forming a first package comprising a first substrate on which bumps are arranged, and a second package comprising a second substrate on which electrode pads corresponding to the bumps are arranged;
applying a solder paste on the bumps; and
electrically connecting the bumps with the electrode pads.

2. The method of claim 1, wherein the electrode pads are mounted on the surface of the second package on which second microelectronic chips are formed, and are arranged on an outer edge of the second substrate.

3. The method of claim 1, wherein applying the solder paste includes dipping the bumps in the solder paste to a substantially uniform thickness.

4. The method of claim 3, wherein the solder paste fills a pool of a reservoir using a squeegee.

5. A method of manufacturing a multi-stack package, the method comprising:
forming a first package comprising a first substrate on which bumps are arranged, and a second package comprising a second substrate on which electrode pads corresponding to the bumps are arranged;
applying a flux on the bumps; and
electrically connecting the bumps with the electrode pads.

6. The method of claim 5, wherein the electrode pads are mounted on the surface of the second package on which second microelectronic chips are formed, and are arranged on an outer edge of the second substrate.

7. The method of claim 5, wherein applying the flux includes dipping the bumps in the flux to a substantially uniform thickness.

8. The method of claim 7, wherein the flux fills a pool of a reservoir using a squeegee.

9. A method of manufacturing a multi-stack package, the method comprising:
forming a first package comprising a first substrate on which bumps are arranged, and a second package comprising a second substrate on which electrode pads corresponding to the bumps are arranged;
applying a solder paste on the electrode pads using a dotting tool; and
electrically connecting the bumps with the electrode pads.

10. The method of claim 9, wherein the electrode pads are mounted on the surface of the second package on which second microelectronic chips are formed, and are arranged on an outer edge of the second substrate.

11. The method of claim 9, wherein applying the solder paste includes applying the solder paste on the electrode pads after the dotting tool is loaded with the solder paste, and the dotting tool is a cylinder-type dotting tool.

12. The method of claim 9, wherein applying the solder paste includes applying the solder paste on the electrode pads after the dotting tool is loaded with the solder paste, and the dotting tool is a rod-type dotting tool.

13. A method of manufacturing a multi-stack package, the method comprising:
forming a first package comprising a first substrate on which bumps are arranged, and a second package comprising a second substrate on which electrode pads corresponding to the bumps are arranged;
applying a flux on the electrode pads using a dotting tool; and
electrically connecting the bumps and the electrode pads.

14. The method of claim 13, wherein the electrode pads are mounted on the surface of the second package on which second microelectronic chips are formed, and are arranged on an outer edge of the second substrate.

15. The method of claim 13, wherein applying the flux includes applying the flux on the electrode pads after the dotting tool is loaded with the flux, and the dotting tool is a cylinder-type dotting tool.

16. The method of claim 13, wherein applying the flux includes applying the flux on the electrode pads after the dotting tool is loaded with the flux, and the dotting tool is a rod-type dotting tool.
